(19) United States
(12) Patent Application Publication
(10) Pub. No.: US 2014/0197150 A1
(43) Pub. Date: Jul. 17, 2014

(54) CONTROL PANEL FOR AN APPLIANCE AND A METHOD FOR PRODUCING A CONTROL PANEL FOR AN APPLIANCE

(71) Applicant: GENERAL ELECTRIC COMPANY, Schenectady, NY (US)

(72) Inventors: Raja Gopal Varhabhatla, Louisville, KY (US); Sudhaker Rao Veldhi, Louisville, KY (US); Derrick Douglas Little, Louisville, KY (US)

(73) Assignee: GENERAL ELECTRIC COMPANY, Schenectady, NY (US)

(21) Appl. No.: 13/740,530

(22) Filed: Jan. 14, 2013

(51) Int. Cl. F24C 7/08; H05K 13/00; H03K 17/96

(52) U.S. Cl. CPC F24C 7/087; H03K 17/9622; H05K 13/00
USPC 219/419; 29/829; 29/832; 29/458

(57) ABSTRACT

A control panel for an appliance is provided. The control panel can be produced by providing a dielectric substrate having a front surface and a back surface, printing a conductive ink onto the back surface of the dielectric substrate, curing the conductive ink such that the conductive ink forms a plurality of capacitive sensors on the back surface of the dielectric substrate, and positioning the dielectric substrate on the appliance such that the front surface of the dielectric substrate faces outwardly.

### FIELD OF THE INVENTION

The present subject matter relates generally to control panels for appliances and methods for producing the same.

### BACKGROUND OF THE INVENTION

Appliances generally include a control panel having a plurality of buttons, keys, or other input devices. Utilizing the control panel, an appliance user can input control commands to the appliance and operate the appliance. Certain control panels include capacitive touch sensors that utilize a user's body capacitance to operate. In particular, capacitive touch sensors can detect an increase in capacitance when the user touches the control panel.

Generally, control panels include a dielectric panel and a separate printed circuit board or plastic ribbon strip. Capacitive touch sensors can be formed on the printed circuit board or printed onto the plastic ribbon strip, and the printed circuit board or plastic ribbon strip can be mounted to a back surface of the dielectric panel. When a user touches a front surface of the dielectric panel, the capacitive touch sensors on the printed circuit board or plastic ribbon strip can detect a change in capacitance and signal the appliance.

However, forming capacitive touch sensors on a printed circuit board and printing capacitive touch sensors on a plastic ribbon strip have certain drawbacks. In particular, the printed circuit boards are separate components that are secured to the control panel's dielectric panel, but securing the printed circuit boards to the dielectric panel can be difficult and unreliable. Over time, the printed circuit board can separate from the dielectric panel and negatively affect operation of the control panel. Similarly, the plastic ribbon strips are separate components that are secured to the control panel's dielectric panel, and, the plastic ribbon strips can also separate from the dielectric panel over time. Also, plastic ribbon strips can be expensive to manufacture and can increase an overall cost of an associated appliance.

Accordingly, a control panel for an appliance that is reliable and inexpensive would be useful. Further, a method for producing a reliable and inexpensive control panel for an appliance would be useful.

### BRIEF DESCRIPTION OF THE INVENTION

The present subject matter provides a control panel for an appliance. The control panel can be produced by providing a dielectric substrate having a front surface and a back surface, printing a conductive ink onto the back surface of the dielectric substrate, curing the conductive ink such that the conductive ink forms a plurality of capacitive sensors on the back surface of the dielectric substrate, and positioning the dielectric substrate on the appliance such that the front surface of the dielectric substrate faces outwardly. Additional aspects and advantages of the invention will be set forth in part in the following description, or may be apparent from the description, or may be learned through practice of the invention.

In a first exemplary embodiment, a method for producing a control panel for an appliance is provided. The method including providing a dielectric substrate having a front surface and a back surface. The front and back surfaces are positioned opposite each other on the dielectric substrate. The method also includes printing a conductive ink onto the back surface of the dielectric substrate, curing the conductive ink such that the conductive ink forms a plurality of capacitive sensors on the back surface of the dielectric substrate, positioning the dielectric substrate on the appliance such that the front surface of the dielectric substrate faces outwardly and at least one of the capacitive sensors on the back surface of the dielectric substrate is triggered when a user touches the front surface of the dielectric substrate.

In a second exemplary embodiment, an appliance is provided. The appliance includes a cabinet and a control panel mounted to the cabinet. The control panel includes a dielectric substrate having a front surface and a back surface. The front and back surfaces are positioned opposite each other on the dielectric substrate. A plurality of capacitive sensors is printed onto the back surface of the dielectric substrate. The dielectric substrate is positioned on the cabinet such that the front surface of the dielectric substrate faces outwardly and at least one of the capacitive sensors is triggered when a user touches the front surface of the dielectric substrate.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 provides a perspective view of a range appliance according to an exemplary embodiment of the present subject matter.

FIG. 2 provides a schematic view of the range appliance of FIG. 1.

FIG. 3 provides a front, elevation view of a control panel according to an exemplary embodiment of the present subject matter.

FIG. 4 provides a rear, elevation view of the control panel of FIG. 3.

FIG. 5 provides a section view of the control panel of FIG. 3 taken along the 5-5 line of FIG. 3.

FIG. 6 illustrates a method for producing a control panel for an appliance according to an exemplary embodiment of the present subject matter.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

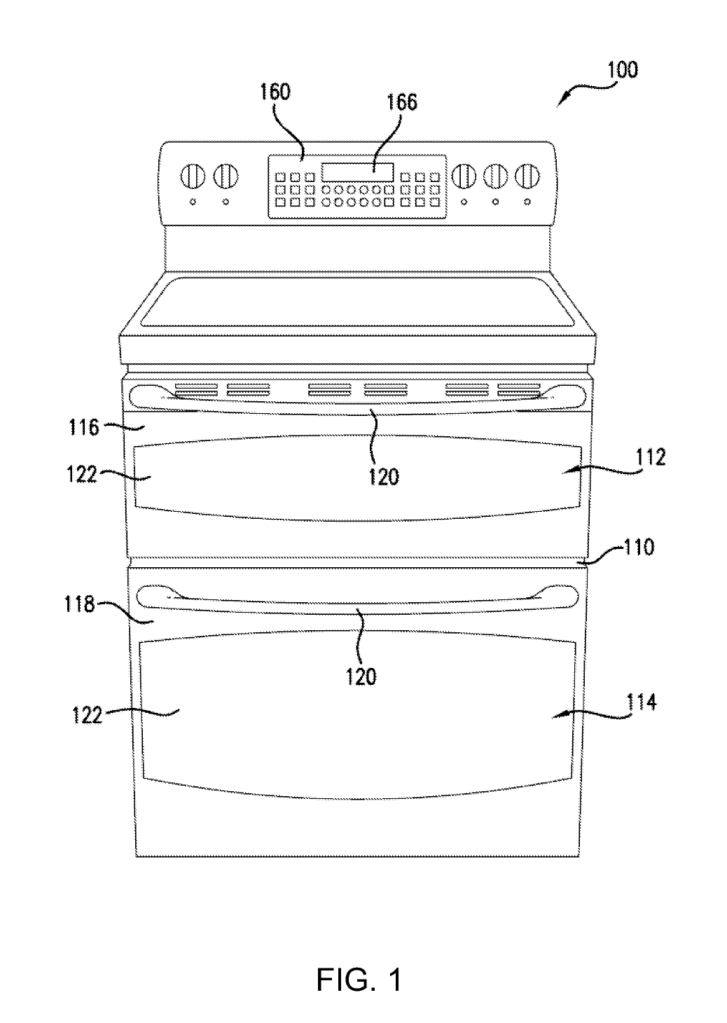

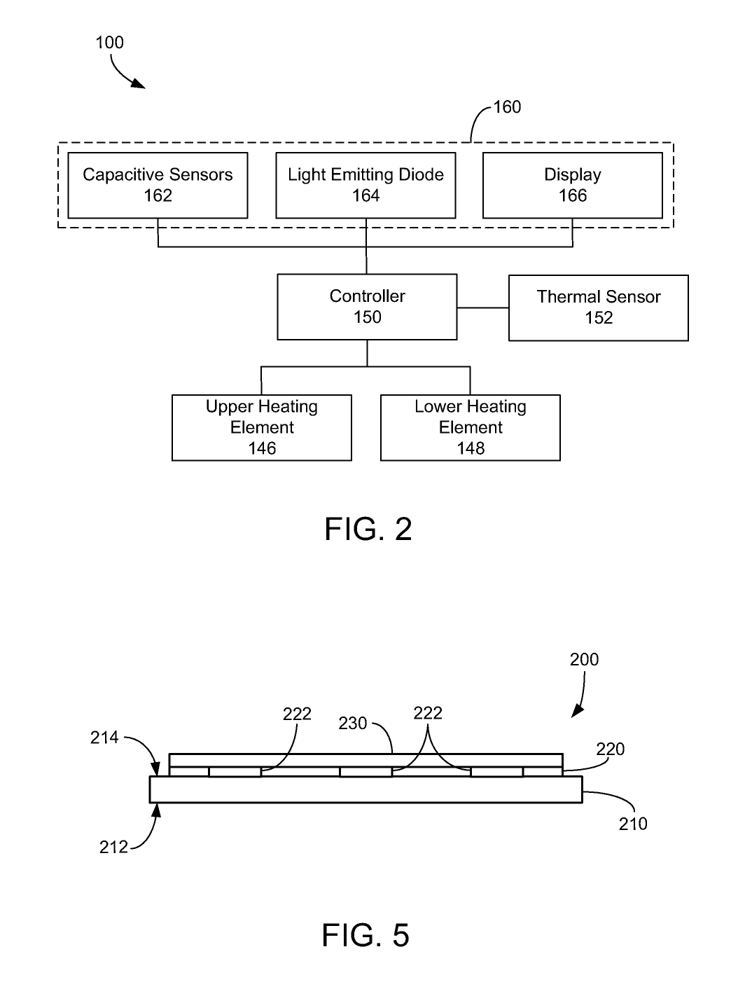

FIG. 1 provides a perspective view of a range appliance 100 according to an exemplary embodiment of the present subject matter. FIG. 2 provides a schematic view of range appliance 100. As will be understood by those skilled in the art, range appliance 100 is provided by way of example only, and the present subject matter may be used in any suitable appliance, e.g., an oven appliance, a refrigerator appliance, a dishwasher appliance, a dryer appliance, and/or a washing machine appliance. Thus, the exemplary embodiment shown in FIG. 1 is not intended to limit the present subject matter in any aspect.

Range appliance 100 includes an insulated cabinet 110. Cabinet 110 defines an upper cooking chamber 112 and a lower cooking chamber 114. Thus, range appliance 100 is generally referred to as a double oven range appliance. Cooking chambers 112 and 114 are configured for the receipt of one or more food items to be cooked. Range appliance 100 includes an upper door 116 and a lower door 118 rotatably attached to cabinet 110, e.g., with a hinge (not shown), in order to permit selective access to upper cooking chamber 112 and lower cooking chamber 114, respectively. Handles 120 are mounted to upper and lower doors 116 and 118 to assist a user with opening and closing doors 116 and 118 in order to access cooking chambers 112 and 114. As an example, a user can pull on handle 120 mounted to upper door 116 to open or close upper door 116 and access upper cooking chamber 112. Glass window panes 122 provide for viewing the contents of upper and lower cooking chambers 112 and 114 when doors 116 and 118 are closed and also assist with insulating upper and lower cooking chambers 112 and 114.

An upper heating element 146 (FIG. 2) and a lower heating element 148 (FIG. 2) are positioned within upper cooking chamber 112 and lower heating chamber 114 of cabinet 110, respectively. Upper and lower heating elements 146 and 148 are used to heat upper cooking chamber 112 and lower heating chamber 114, respectively, for both cooking and cleaning of range appliance 100. The size and heat output of upper and lower heating elements 146 and 148 can be selected based on the e.g., the size of range appliance 100. Upper and lower heating elements 146 and 148 can include any suitable mechanism for heating oven appliance 100. For example, upper and lower heating elements 146 and 148 can include electric heating elements, microwave heating elements, halogen heating elements, or suitable combinations thereof.

Operation of the range appliance 100 is regulated by a controller 150 that is operatively coupled to a control panel 160. Control panel 160 includes capacitive sensors 162, light emitting diodes 164, and a display 166. Control panel 160 may be in communication with controller 150 via one or more signal lines or shared communication busses. Control panel 160 provides selections for user manipulation of the operation of range appliance 100. For example, a user can touch control panel 160 to trigger one of capacitive sensors 162 and signal controller 150. In response to user manipulation of capacitive sensors 162, controller 150 operates various components of the range appliance 100. For example, controller 150 is operatively coupled or in communication with upper and lower heating elements 146 and 148.

Light emitting diodes 164 can operate to indicate certain operations of range appliance 100 to a user. For example, light emitting diodes 164 can inform the user whether range appliance 100 is operating in a bake or broil mode. Similarly, display 166 can present information to an appliance user. For example, display 166 can show the current time or the operating temperature of upper and/or lower cooking chambers 112 and 114. Display 166 can be a liquid crystal display or any other suitable mechanism for displaying information to an appliance user.

Controller 150 is also in communication with a thermal sensor 152, e.g., a thermocouple or thermistor. Temperature sensor 152 may be positioned in one of upper and lower heating chambers 112 and 114. Controller 150 may receive a signal from temperature sensor 152 that corresponds to a temperature of upper heating chamber 112 and/or lower heating chamber 114.

Controller 150 includes memory and one or more processing devices such as microprocessors, CPUs or the like, such as general or special purpose microprocessors operable to execute programming instructions or micro-control code associated with operation of range appliance 100. The memory can represent random access memory such as DRAM, or read only memory such as ROM or FLASH. The processor executes programming instructions stored in the memory. The memory can be a separate component from the processor or can be included onboard within the processor. Alternatively, controller 150 may be constructed without using a microprocessor, e.g., using a combination of discrete analog and/or digital logic circuitry (such as switches, amplifiers, integrators, comparators, flip-flops, AND gates, and the like) to perform control functionality instead of relying upon software.

Controller 150 may be positioned in a variety of locations throughout range appliance 100. Input/output (“I/O”) signals may be routed between controller 150 and various operational components of range appliance 100, e.g., via one or more signal lines or shared communication busses.

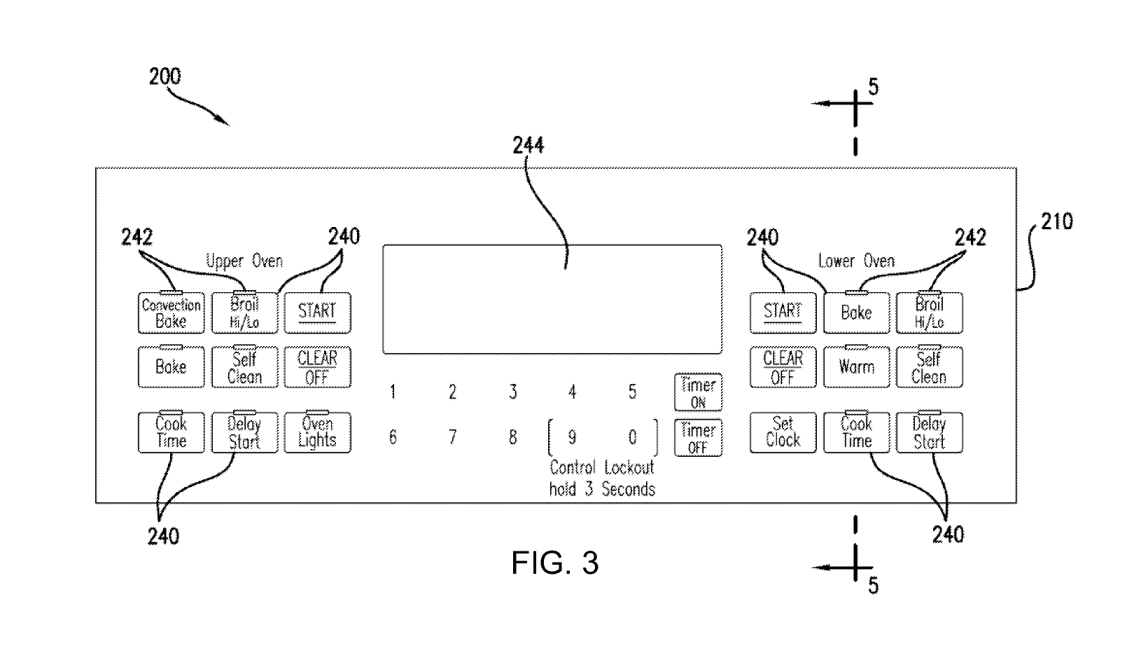

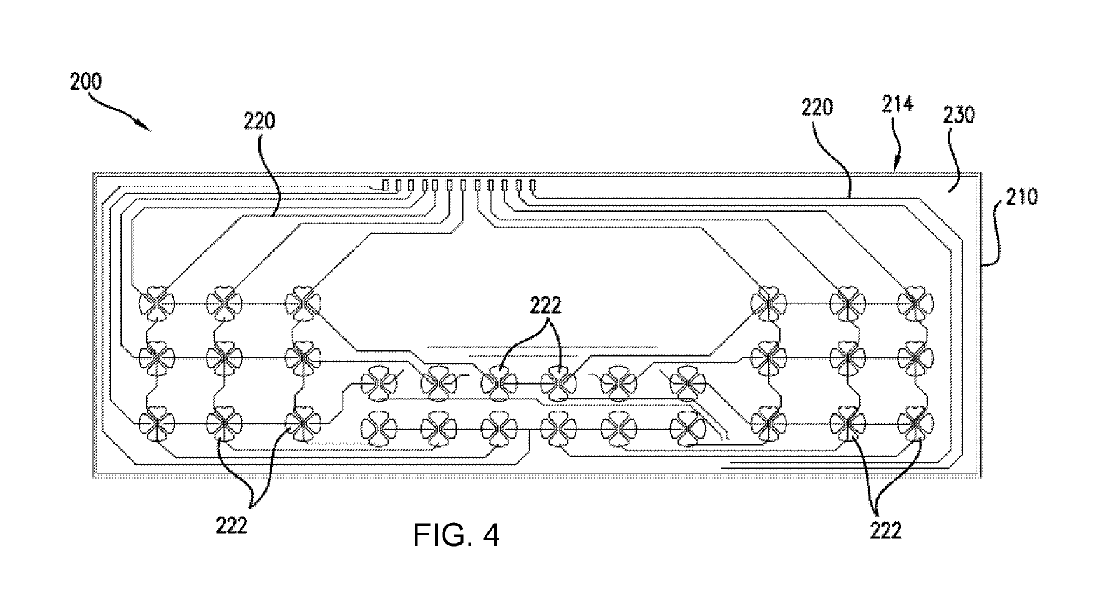

FIG. 3 provides a front, elevation view of a control panel 200 according to an exemplary embodiment of the present subject matter. FIG. 4 provides a rear, elevation view of control panel 200. FIG. 5 provides a section view of control panel 200 taken along the 5-5 line of FIG. 3. Control panel 200 is shown configured for use in a double oven range appliance, such as range appliance 100 (FIG. 1). However, as will be understood by those skilled in the art using the teachings disclosed herein, the present subject matter may be configured for use in any suitable appliance.

Control panel 200 includes a dielectric substrate 210 having a front surface 212 and a back surface 214. Front surface 212 of dielectric substrate 210 and back surface 214 of dielectric substrate 210 are positioned opposite each other on dielectric substrate 210. Dielectric substrate 210 may be constructed of any suitable material. For example, dielectric substrate 210 may be constructed of glass or plastic, such as a transparent glass or plastic.

A plurality of capacitive sensors 222 is printed, e.g., directly, onto back surface 214 of dielectric substrate 210. Capacitive sensors 222 are constructed with a conductive ink 220. As an example, conductive ink 220 can contain silver, e.g., more than about seventy-five percent silver and less than one-hundred percent silver. In particular, conductive ink 220 can be DuPont 7723. As may be seen in FIG. 3, conductive ink 220 can also electrically connect capacitive sensors 222, e.g., to one another and controller 150 (FIG. 2).

Capacitive sensors 222 are configured for triggering when a user touches front surface 212 of dielectric substrate 210. In particular, capacitive sensors 222 can detect when a conductive material or any material with a dielectric different than air contacts or approaches dielectric substrate 210. As an example, dielectric substrate 210 can be positioned on cabinet 110 such that front surface 212 of dielectric substrate 210 faces outwardly. When a user touches front surface 212 of dielectric substrate 210 adjacent one of capacitive sensors 222, such capacitive sensor 222 triggers and, e.g., signals controller 150. In such a manner, operations of an appliance can be initiated and controlled.

Control panel 200 further includes a plurality of appliance function indicators 240 positioned on dielectric substrate 210. Each one of appliance function indicators 240 can be positioned adjacent and correspond to one of capacitive sensors 222 positioned on back surface 214 of dielectric substrate 210. Appliance function indicators 240 are visible on front surface 212 of dielectric substrate 210, e.g., in order to guide user operation of control panel 200. As an example, each appliance function indicator 240 can include a distinct message or symbol corresponding to the appliance function associated with the underlying capacitive sensor 222. Appliance function indicators 240 may be positioned directly on dielectric substrate 210. For example, appliance function indicators 240 may be printed or produced onto front surface 212 or back surface 214 of dielectric substrate 210.

Control panel 200 also includes a conformal coating 230 disposed over capacitive sensors 222 on back surface 214 of dielectric substrate 210. In additional exemplary embodiments, conformal coating 230 may be disposed over exposed portions of back surface 214 of dielectric substrate 210. Conformal coating 230 can assist with reducing electromagnetic interface of capacitive sensors 222. Also, conformal coating 230 can assist with dissipating heat within control panel 200. Conformal coating 230 can be constructed of any suitable material. For example, conformal coating 230 can include an acrylic, an epoxy, a polyurethane, silicon, a parylene, a fluoropolymer, and combinations thereof.

In additional alternative embodiments, control panel 200 includes light emitting diodes 242, e.g., light emitting diodes 164 (FIG. 2), mounted on back surface 214 of dielectric substrate 210 at respective ones of capacitive sensors 222. Light emitting diodes 242 can indicate or signal certain appliance operations. For example, light emitting diodes 242 can emit light when range appliance 100 is operating and upper and/or lower heating elements 146 and 148 are active.

In other alternative embodiments, control panel 200 includes a display 244, such as display 166, soldered onto back surface 214 of dielectric substrate 210. Display 244 can display information to an appliance user. For example, display 244 can show the current time or the operating temperature of upper and/or lower cooking chambers 112 and 114.

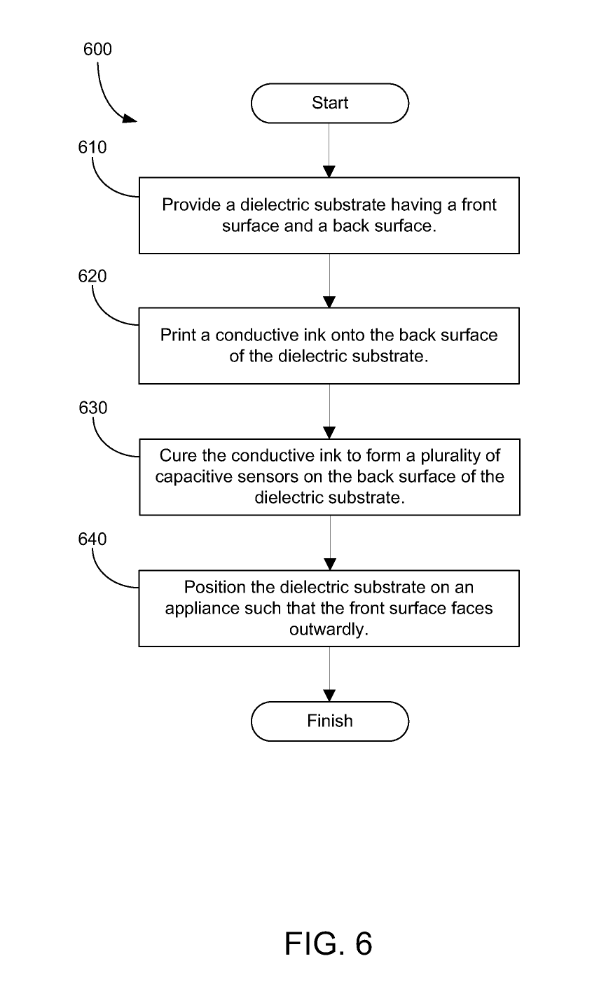

FIG. 6 illustrates a method 600 for producing a control panel for an appliance according to an exemplary embodiment of the present subject matter. Method 600 can be utilized to produce control panel 200 (FIG. 2) and/or control panel 160 (FIG. 1). Utilizing method 600, control panel 200 can be produced cheaply. Also, method 600 can improve a robustness of durability of control panel 200.

At step 610, dielectric substrate 210 is provided. As discussed above, dielectric substrate 210 has front surface 212 and back surface 214 positioned opposite each other on dielectric substrate 210. At step 620, conductive ink 220 is printed, e.g., directly, onto back surface 214 of dielectric substrate 210, e.g., into the shapes of capacitive sensors 222. At step 630, conductive ink 220 is cured such that conductive ink 220 forms capacitive sensors 222 on back surface 214 of dielectric substrate 210.

At step 640, dielectric substrate 210 is positioned on an appliance, such as range appliance 100, such that front surface 212 of dielectric substrate 210 faces outwardly. In such a position, at least one of capacitive sensors 222 on back surface 214 of dielectric substrate 210 is triggered when a user touches front surface 212 of dielectric substrate 210.

In additional exemplary embodiments, method 600 can also include marking appliance function indicators 240 on dielectric substrate 210. For example, appliance function indicators 240 may be printed, applied, or produced directly onto front surface 212 or back surface 214 of dielectric substrate 210. As discussed above, appliance function indicators 240 are visible on or from front surface 212 of dielectric substrate 210.

In additional exemplary embodiments, method 600 also includes mounting light emitting diode 242 onto back surface 214 of dielectric substrate 210, e.g., onto conductive ink 220, at one of capacitive sensors 222. Further, method 600 can include soldering display 244 onto back surface 214 of dielectric substrate 210, e.g., onto conductive ink 220. Method 600 can also include applying conformal coating 230 onto capacitive sensors 222 and exposed portions of back surface 214 of dielectric substrate 210.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method for producing a control panel for an appliance, comprising:
providing a dielectric substrate having a front surface and a back surface, the front and back surfaces positioned opposite each other on the dielectric substrate;
printing a conductive ink onto the back surface of the dielectric substrate;
curing the conductive ink such that the conductive ink forms a plurality of capacitive sensors on the back surface of the dielectric substrate; and
positioning the dielectric substrate on the appliance such that the front surface of the dielectric substrate faces outwardly and at least one of the capacitive sensors on the back surface of the dielectric substrate is triggered when a user touches the front surface of the dielectric substrate.

2. The method of claim 1, further comprising marking a plurality of appliance function indicators on the dielectric substrate, each one of the appliance function indicators positioned adjacent and corresponding to one of the capacitive sensors, the appliance function indicators being visible on the front surface of the dielectric substrate.

3. The method of claim 2, wherein the appliance function indicators are marked directly on the dielectric substrate.

4. The method of claim 1, further comprising mounting a light emitting diode on the back surface of the dielectric substrate at one of the capacitive sensors.

5. The method of claim 1, further comprising soldering a display onto the back surface of the dielectric substrate.

6. The method of claim 5, wherein the display is a liquid crystal display.

7. The method of claim 1, further comprising applying a conformal coating onto the capacitive sensors.

8. The method of claim 7, wherein said step of applying further comprises coating exposed portions of the back surface of the dielectric substrate with the conformal coating.

9. The method of claim 7, wherein the conformal coating comprises at least one of an acrylic, an epoxy, a polyurethane, silicon, a parylene, and a fluoropolymer.

10. The method of claim 7, wherein the conductive ink comprises about seventy-five percent silver.

11. An appliance comprising:
a cabinet;
a control panel mounted to said cabinet, said control panel comprising
a dielectric substrate having a front surface and a back surface, the front and back surfaces positioned opposite each other on said dielectric substrate;
a plurality of capacitive sensors printed onto the back surface of said dielectric substrate;
wherein said dielectric substrate is positioned on said cabinet such that the front surface of said dielectric substrate faces outwardly and at least one of said capacitive sensors is triggered when a user touches the front surface of the dielectric substrate.

12. The appliance of claim 11, wherein said control panel further comprises a plurality of appliance function indicators positioned on said dielectric substrate, each one of said appliance function indicators positioned adjacent and corresponding to one of said capacitive sensors, said appliance function indicators being visible on the front surface of said dielectric substrate.

13. The appliance of claim 11, wherein said appliance function indicators are positioned directly on said dielectric substrate.

14. The appliance of claim 11, wherein said control panel further comprises a light emitting diode mounted on the back surface of said dielectric substrate at one of said capacitive sensors.

15. The appliance of claim 11, wherein said control panel further comprises a display soldered onto the back surface of said dielectric substrate.

16. The appliance of claim 15, wherein said display comprises a liquid crystal display.

17. The appliance of claim 11, wherein said control panel further comprises a conformal coating disposed over said capacitive sensors on the back surface of said dielectric substrate.

18. The appliance of claim 17, wherein said conformal coating is also disposed over exposed portions of the back surface of said dielectric substrate.

19. The appliance of claim 17, wherein said conformal coating comprises at least one of an acrylic, an epoxy, a polyurethane, silicon, a parylene, and a fluoropolymer.

20. The appliance of claim 11, wherein said capacitive sensors are constructed with a material having about seventy-five percent silver.
